(19) United States
(12) Patent Application Publication
(10) Pub. No.: US 2018/0211867 A1
(43) Pub. Date: Jul. 26, 2018

(54) METHOD FOR MANUFACTURING DUAL DAMASCENE STRUCTURES

(71) Applicants: UNITED MICROELECTRONICS CORP., Hsin-Chu City (TW); Fujian Jinhua Integrated Circuit Co., Ltd., Quanzhou City (CN)

(72) Inventors: Hsin-Yu Chiang, Kaohsiung City (TW); Feng-Yi Chang, Tainan City (TW); Fu-Che Lee, Taichung City (TW)

(21) Appl. No.: 15/866,469

(22) Filed: Jan. 10, 2018

(30) Foreign Application Priority Data
Jan. 23, 2017 (CN) 201710058124.9

(51) Int. Cl. H01L 21/768; H01L 21/311

(52) U.S. Cl. CPC H01L 21/76808; H01L 21/31138; H01L 21/31116

(57) ABSTRACT

A method for manufacturing dual damascene structures is provided with the steps of forming a via hole through a dielectric layer, forming a sacrificial layer on the dielectric layer filling up the via hole, performing an etch process through a photoresist to form a trench in the dielectric layer, wherein in the etch process the ratio of etching selectivity between the dielectric layer and the sacrificial layer is 1:1, and the trench and the via hole forms collectively a dual damascene recess.

### BACKGROUND OF THE INVENTION

### 1. Field of the Invention

The present invention relates generally to a method for manufacturing dual damascene structures, and more specifically, to a method for manufacturing dual damascene structures using improved patterning process.

### 2. Description of the Prior Art

The escalating requirements for high density and performance associated with ultra large scale integration semiconductor wiring require increasingly sophisticated interconnection technology. As device sizes decrease it has been increasingly difficult to provide interconnection technology that satisfies the requirements of low resistance and capacitance interconnect properties, particularly where submicron inter-layer damascene interconnects (e.g., vias) and intra-layer interconnects having increasing aspect ratios (opening depth to diameter ratio).

In particular, in forming a dual damascene by a via-first method where the via opening is first formed in one or more dielectric insulating layers followed by forming an overlying and encompassing trench opening for forming a metal interconnect line, several processing steps are required which entail exposing the via opening to dry etching chemistries. As a result, the sidewalls of the via are subject to etching which causes variation in the via opening profile leading to undesirable variations in via electrical resistances and capacitances in the completed metal filled damascene.

For this reason, the current method for manufacturing dual damascene structures in semiconductor manufacture industry need to be improved, to reduce the impact of via subject to the etch process as well as reduce the process cycle to increase throughput.

### SUMMARY OF THE INVENTION

It is therefore an object of the invention to provide an improved dual damascene manufacturing method with less number of required etch processes through controlling the etch selectivity of critical layer structures, to maintain the profile of defined via hole and reduce the process cycle of the manufacture.

One objective of the present invention is to provide a method of manufacturing dual damascene structures including the steps of forming a via hole through a dielectric layer, forming a sacrificial layer filling the via hole on the dielectric layer, performing an etch process with a photoresist to form a trench in the dielectric layer, wherein in the etch process the ratio of etching selectivity between the dielectric layer and the sacrificial layer is 1:1, and the trench and the via hole forms collectively a dual damascene recess.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute apart of this specification. The drawings illustrate some of the embodiments and, together with the description, serve to explain their principles. In the drawings:

FIGS. 1-6 are schematic cross-sectional views illustrating the process flow of manufacturing dual damascene structures in accordance with the embodiment of present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following detailed description of the present invention, reference is made to the accompanying drawings which form a part hereof and is shown by way of illustration and specific embodiments in which the invention may be practiced. These embodiments are described in sufficient details to enable those skilled in the art to practice the invention. Other embodiments may be utilized and structural, logical, and electrical changes may be made without departing from the scope of the present invention. The following detailed description, therefore, is not to be taken in a limiting sense, and the scope of the present invention is defined by the appended claims.

Although the method of the present invention is explained by exemplary reference the formation of a via-first method of formation of a dual damascene structure in a multi-level semiconductor device, it will be appreciated that the method of the present invention is equally applicable to forming a structure where one etched opening is formed overlying and at least partially encompassing one or more underlying etched openings. The method of the present invention is particularly advantageous in preventing damage to underlying vias and photoresist poisoning in the trench formation process, while reducing a number of processing steps. Furthermore, while the method of the present invention is explained with exemplary reference to the formation of a copper filled dual damascene structure, it will be appreciated that the method is applicable where other metals, for example tungsten, aluminum, copper, or alloys thereof including the use of various types of adhesion/barrier liners.

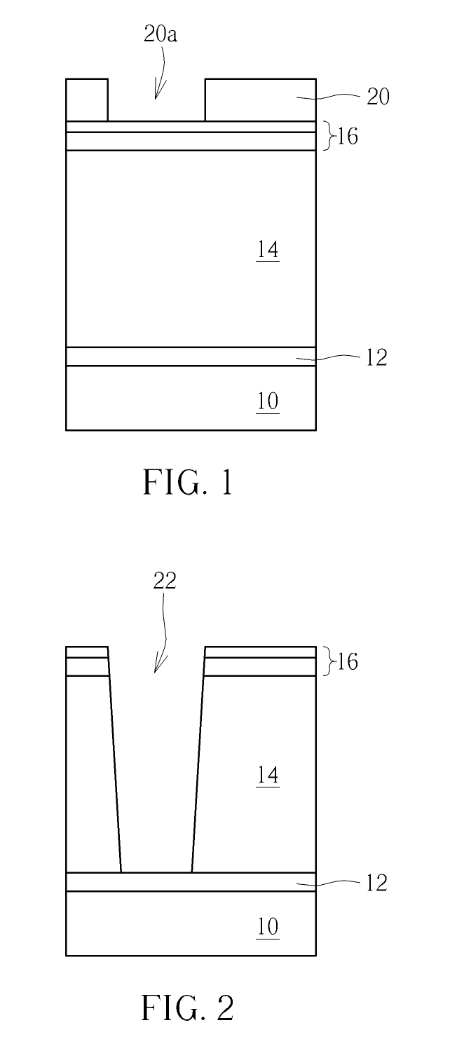

FIGS. 1-5 are schematic cross-sectional views illustrating the process flow of manufacturing dual damascene structures in accordance with the embodiment of present invention. The following detailed description is made with reference to those accompanying drawings to explain the process steps of forming the dual damascene structures.

Please refer to FIG. 1. A substrate 10 is first provided with conductive regions (not shown) formed thereon, such as copper wirings formed in advance in insulating dielectric layers. For the clarity of the disclosure and not obscuring the key points of the present invention, a blank substrate 10 is used in the drawings to represent all components formed therein. An etch stop layer 12 is formed on the substrate 10. The etch stop layer 12 may be a layer made of silicon nitride (SiNₓ), silicon oxynitride (SiON), silicon carbide (SiC) or silicon carbonitride (SiCN) by common chemical vapor deposition (CVD) process. A dielectric layer 14, such as an inter-metal dielectric (IMD), is formed on the etch stop layer 12. The dielectric layer 14 is preferably made of low-K dielectric material, such as fluorosilicate glass (FSG) or organo-silicate glass (OSG). In the embodiment of present invention, the dielectric layer 14 is the layer where the dual damascene structures are to be formed.

Refer again to FIG. 1. A capping layer 16 is formed on the dielectric layer 14. In the embodiment of present invention, the capping layer 16 may function as an anti-reflective coating with multilayer, such as a combination of one silicon oxynitride layer and one silicon oxide layer, to improve the anti-reflective efficiency in the process. The capping layer 16 may be formed by conventional plasma-enhanced chemical vapor deposition (PECVD) process. A photoresist 20, such as a positive photoresist, is formed on the capping layer 16, wherein the photoresist is provided with a via hole pattern 20a that may be defined by conventional photolithographic process after the formation.

Please refer to FIG. 2. An etch process, such as reactive ion etching (RIE), is then performed by using the photoresist with via hole pattern as an etch mask to form via hole 22 in the underlying dielectric layer and expose the etch stop layer 12 thereunder.

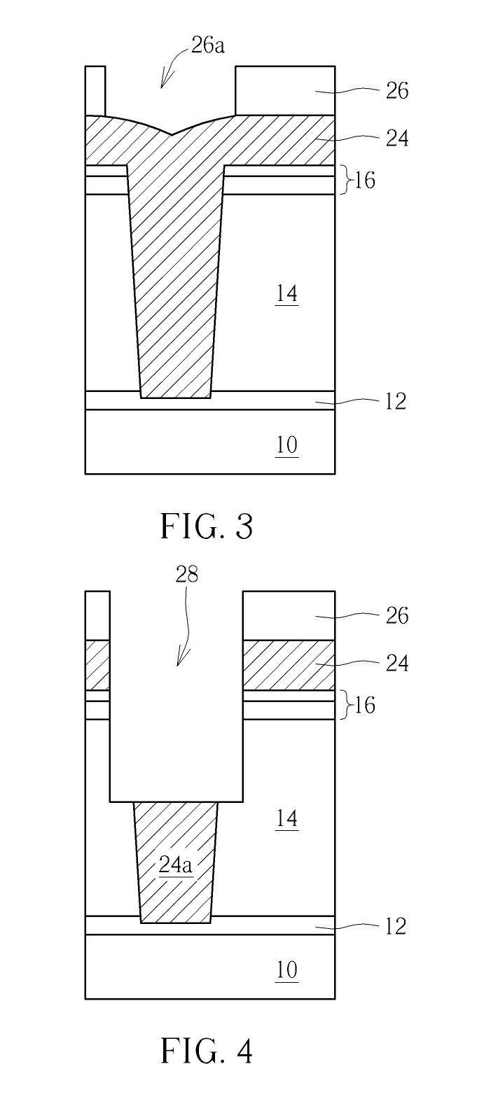

Please refer to FIG. 3. After the via hole 22 is formed, the photoresist 20 is removed and a sacrificial layer 24 is then formed on the capping layer 24 filling up the via hole 22. In the embodiment of present invention, the sacrificial layer 24 may be formed by blanket deposition, such as a spin coating process or a flowable chemical vapor deposition (FCVD) process. The material of sacrificial layer is preferably flowable. Normal carbon-based photoresist, bottom anti-reflective coating (BARC) or organic dielectric layer (ODL) is appropriate to be used in this process. A curing process is then performed to remove the solvent in these flowable materials. Thereafter, a photoresist 26, such as a positive photoresist, is formed on the sacrificial layer 24. The photoresist 26 is provided with a trench pattern 26a overlapping the via hole 22 below. The trench pattern 26a may be formed with a width preferably larger than the width of via hole 22 through conventional photolithographic process.

Please refer to FIG. 4. After the sacrificial layer 24 and the photoresist 26 are formed, an etch process, such as a RIE process, is then performed using the photoresist 26 with trench pattern 26a as an etch mask to form trench in the underlying dielectric layer 14. Please note that the key point of this etch process in the embodiment is that the ratio of etch selectivity between the sacrificial layer 24 and surrounding dielectric layer 14 is set at about 1:1, for example, about 0.9-1.1. Through this design, the sacrificial layer 24 and the dielectric layer 14 would be subject to equivalent etching force and the same etching depth would be reached in both layers in the etch process, so as to form a recess 28, while other sacrificial layer 24a is left in the via hole. Specifically, the ratio of etch selectivity between the sacrificial layer 24 and the capping layer 16 may be controlled at about 1:1 in the beginning of etch process. The ratio of etch selectivity between the sacrificial layer 24 and the dielectric layer 14 are adjusted later to reach the value about 1:1 by switching to different etching gases. This approach is different from the current regular process, which only the sacrificial layer 24 is etched off and the dielectric layer 14 remains. Furthermore, because this process difference, the advantage of the present invention is that the recess 28 of dual damascene structure is concurrently formed in this process without additional etch process for forming the trench in the dielectric layer after the etch back of the sacrificial layer 24. In the embodiment of present invention, the number of etch process required to form the dual damascene recess is reduced and the issue of undesired dual damascene profile caused by the over etching of dielectric layer is, therefore, properly solved.

Additionally, in order to facilitate the control of etch processes or to meet the process requirement, another etch stop layer may be optionally prepared in the dielectric layer to define the depth of recess 28 bottom.

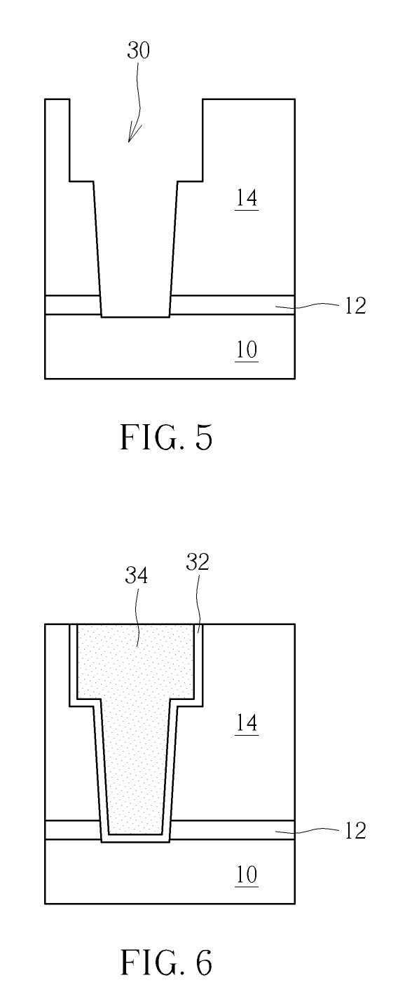

Please refer to FIG. 5. After the recess 28 is formed, a strip process is performed to remove unnecessary portions, including the photoresist 26, the sacrificial layer 24/24a and the capping layer 16, etc. The strip process may also remove the etch stop layer 12 in via hole to expose the substrate 10 thereunder. The strip process may include several steps, for example, including one plasma ashing process to remove the photoresist above and remaining organic sacrificial layer 24/24a and one plasma etch process to remove the capping layer 16 and the exposed etch stop layer 12. In this way, the recess 28 and the underlying via hole 22 collectively form the dual damascene trench 30 of the present invention.

In the preferred embodiment, the steps of etch process shown in FIG. 4 and the strip process shown in FIG. 5 may be performed in different process chambers of one process tool, or may be performed in single chamber through the switch of different etching gases.

In other embodiment of the present invention, the above-mentioned strip process may be partly integrated in the process of forming recess 28. For example, set the ratio of etch selectivity between the capping layer 16 and the sacrificial layer 24 at 1:2 rather than 1:1, the removal of the capping layer 16 may therefore be slower than the removal of the sacrificial layer, so that the remaining sacrificial layer 24 in via hole may be etched off when the predetermined depth of the recess 28 is reached. Even the etch stop layer may be removed concurrently in this process to expose the substrate 10 thereunder.

Please refer to FIG. 6. After the dual damascene recess 30 is formed, a barrier layer (or an adhesive layer) 32 and a metal layer 34 is deposited sequentially in the dual damascene recess 30 to form collectively the dual damascene structure. The material of the barrier layer 32 may be tantalum nitride (TaN), and the material of the metal layer 34 may be copper (Cu). Both layers may be formed on the substrate by available electrochemical deposition (ECD). A chemical mechanical polishing (CMP) process is then performed to remove the portion outside the dual damascene recess. The manufacture of the dual damascene structure is, therefore, completed.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for manufacturing dual damascene structures, comprising:
providing a substrate with a dielectric layer;
forming a via hole in said dielectric layer;
forming a sacrificial layer on said substrate filling up said via hole;
forming a photoresist with a trench pattern overlapping said via hole on said sacrificial layer; and
performing an etch process through said photoresist to form a trench in said dielectric layer, wherein in said etch process the ratio of etching selectivity between said dielectric layer and said sacrificial layer is 1:1, and said trench and said via hole forms collectively a dual damascene recess.

2. The method for manufacturing dual damascene structures of claim 1, further comprising removing said sacrificial layer remaining in said via hole after said etch process.

3. The method for manufacturing dual damascene structures of claim 1, further comprising a capping layer between said photoresist and said dielectric layer.

4. The method for manufacturing dual damascene structures of claim 3, wherein in said etch process said etching selectivity between said capping layer and said sacrificial layer are different, so that said etch process also remove all of said sacrificial layer in said via hole.

5. The method for manufacturing dual damascene structures of claim 1, further comprising an etch stop layer between said substrate and said dielectric layer.

6. The method for manufacturing dual damascene structures of claim 5, wherein said etch process also remove said sacrificial layer and said etch stop layer in said via hole.
